(19) United States
(12) Patent Application Publication
(10) Pub. No.: US 2026/0122781 A1
(43) Pub. Date: Apr. 30, 2026

(54) GLASS WAFER AND METHOD FOR PRODUCING SAME

(71) Applicants: Schott AG, Mainz (DE); SCHOTT North America, Inc., Rye Brook, NY (US)

(72) Inventors: Christoph Loho, Mainz (DE); Azatuhi Ayrikyan, Alfortville (FR); Christoph Brüning, Mainz (DE); Martin Letz, Mainz (DE); Markus Heiss-Chouquet, Bischofsheim (DE); Patrick K. Kreski, Southbridge, MA (US); Paige Higby, Southbridge, MA (US); Kevin Tabor, Southbridge, MA (US); Thorsten Damm, Mainz (DE)

(73) Assignees: Schott AG, Mainz (DE); SCHOTT North America, Inc., Rye Brook, NY (US)

(21) Appl. No.: 19/115,946

(22) PCT Filed: Sep. 14, 2023
(86) PCT No.: PCT/EP2023/075271

§ 371 Date: Mar. 27, 2025

(30) Foreign Application Priority Data
Sep. 27, 2022 (DE) 10 2022 124 863.1
Sep. 14, 2023 (WO) PCTEP2023075271

(51) Int. Cl. H05K 1/03; H05K 1/11; H05K 3/00

(52) U.S. Cl. CPC H05K 1/0306; H05K 1/115; H05K 3/002; H05K 3/0029; H05K 2201/09563

(57) ABSTRACT

A glass wafer includes a glass substrate having at least one opening having a surface having two mutually opposite lateral faces and one circumferential edge face, the glass substrate including a glass including a network former and at least one metal oxide. The at least one opening has a maximum lateral dimension of not more than 400 μm. The glass wafer has a thickness of at least 10 μm. A leaching depth of alkali metal ions in the surface of the at least one opening is greater at least by a factor of 1.1 than a leaching depth on the two lateral faces.

### CROSS-REFERENCE TO RELATED APPLICATIONS

This application is a national stage entry under 35 U.S.C. § 371 of International Patent Application No. PCT/EP2023/075271 entitled “GLASS WAFER AND METHOD FOR PRODUCING SAME” filed Sep. 14, 2023, which is incorporated in its entirety herein by reference. International Patent Application No. PCT/EP2023/075271 claims priority to German Patent Application No. 10 2022 124 863.1 filed on Sep. 27, 2022, which is incorporated in its entirety herein by reference.

### BACKGROUND OF THE INVENTION

### Field of the Invention

The present invention relates generally to glass wafers, especially for use as interposers. Further applications include MEMS, glass cores for integrated circuit packaging, antenna-in-package concepts for GHz applications, and further applications of a similar nature. In particular, the present invention relates to glass wafers comprising at least one opening.

### Description of the Related Art

Glass wafers that are used as interposers and/or are suitable for similar applications, for example as MEMS or as glass core for packaging applications have at least one opening, preferably several, and are generally metallized.

For example, it is known that such glass wafers can be produced by a laser treatment, followed by performance of an etching step. In this way, it is possible to obtain glass wafers comprising defined openings. Fields of use are found, for example, in the industrial production of semiconductors.

A glass wafer in the context of the present disclosure generally means a glass in pane form which may, for example, be of round, elliptical or generally rectangular configuration. In particular, the term “glass wafer” thus also includes glass panels or glass panes.

Even though such interposers made of glass have already been known for some time, certain difficulties arise time and again in practice, for example with regard to the mechanical stability of these wafers or the durability of metallizations on these glass wafers. This also relates, for example, to the metallization within the opening itself.

A glass wafer therefore has to be optimized under the following considerations:
metallizations, for example metallic electrodes, must adhere optimally on the surface of the glass, especially within the opening of the glass wafer,
thermal stresses that can arise on signal transfer as a result of the contacting in the glass wafer should be at a minimum in order to enable lasting stability of the interposer, and tensile stresses on the surfaces in particular should be avoided.

Finally, it is important that the glass wafer is mechanically stable, i.e. has good mechanical strength in particular, during the production and use of the semiconductor.

In the past, however, it has been found that there is still need for optimization here, especially with regard to the bond strength of a metal layer on glass and with regard to the mechanical strength of the glass wafer.

Glass wafers can generally be made more mechanically stable by various methods. For example, US patent application US 2009/0220761 A1 describes a method of chemically tempering glass.

It is also known that a laser treatment can lead to a change in composition in a glass body. This is described, for example, by US patent application US 2020/024188 A1.

Sun et al., in Optical Materials, Volume 108, 2020, state that etching of quartz glass with KOH is possible and can lead to formation of a diffusion layer of the etch medium in the surface of the quartz glass. This can increase the resistance of the quartz glass to lasers.

In addition, there are various studies with regard to altering the mechanical and/or chemical properties of a glass or glass ceramic by etching. However, there are no known studies relating to structured glass wafers for use as interposers.

There is thus generally a need for glass wafers having improved mechanical strength, which are simultaneously also configured to have good coatability, especially in such a way that metallizations have good adhesion.

### SUMMARY OF THE INVENTION

It is an object of the invention to provide glass wafers that at least partly alleviate the weaknesses from the prior art. A further object is that of providing a process for producing such glass wafers.

The present invention therefore relates to a glass wafer comprising at least one opening having a surface having two mutually opposite lateral faces and one circumferential edge face. The glass encompassed by the glass substrate comprises at least one network former and at least one metal oxide. The at least one opening has a maximum lateral dimension, especially a diameter, of not more than 400 μm, preferably of not more than 300 μm and more preferably of not more than 200 μm. The maximum lateral delimitation is preferably at least 10 μm. The glass wafer has a thickness of at least 10 μm. The thickness of the wafer is advantageously limited and is not more than 5 mm. Preferred lower limits for the thickness of the wafer are at least 30 μm, for example 50 μm or 100 μm. Preferred upper limits may be 3 mm or 1.5 mm, or even only 1 mm.

It may be the case that the thickness of the glass wafer and the maximum lateral dimension are in a ratio to one another, in order to achieve advantageous strengths of the glass wafer. This aspect ratio of maximum lateral dimension of the opening (for example diameter of the opening) to the thickness of the glass wafer is preferably at least 1:100.

The leaching depth of metal ions, especially of alkali metal ions, especially of lithium, sodium and/or potassium ions, in the surface of the at least one opening is greater at least by a factor of 1.1 than the leaching depth on the two lateral faces, preferably greater by a factor of 1.5, particularly preferably greater by a factor of 2, more preferably greater by a factor 5 and most preferably greater by a factor of 10, where the leaching depth is preferably not more than 15 times greater than on the two lateral faces, which is preferably determined by a ToF-SIMS measurement.

The glass substrate preferably comprises a glass comprising from 30% by weight to 75% by weight of SiO₂, preferably up to 65% by weight of SiO₂.

Such a configuration has a number of advantages.

The glass wafer is generally configured such that it comprises a glass substrate. A glass substrate means a shaped body which is made of glass and which, aside from the shaping, for example cutting-to-size, has not yet undergone any finishing and/or further processing steps, for example a coating operation. The wafer may therefore generally be referred to as a finished substrate. In this sense, the sides and faces of a substrate and a wafer correspond to one another in the context of the present disclosure. Therefore, where reference is made to a lateral face of the glass wafer or an edge face of the wafer, this also corresponds to the lateral face or edge face of the glass substrate.

The glass wafer or glass substrate is preferably generally in pane form or in planar form. The thickness of the glass wafer or glass substrate is therefore the smallest lateral dimension thereof, in particular smaller than the length and width thereof, or, in the case of a round wafer/substrate, smaller than the diameter thereof.

The glass wafer has at least one opening having a maximum lateral dimension of not more than 400 μm, preferably of not more than 300 μm and more preferably of not more than 200 μm, and may also be much smaller depending on the exact configuration. The opening may generally also be referred to as a “via”.

The glass encompassed by the glass substrate and accordingly by the glass wafer is not a one-component glass and accordingly comprises not only a network former but generally metal oxides in particular.

This is advantageous since, in this way, a simple and inexpensive mode of production of the wafer is also possible by means of customary melting methods, unlike in the case of quartz glass.

The leaching depth of metal ions, especially of alkali metal ions, especially of lithium, sodium and/or potassium ions, in the surface of the at least one opening is greater at least by a factor of 1.1 than the leaching depth on the two lateral faces, preferably greater by a factor of 1.5, particularly preferably greater by a factor of 2, more preferably greater by a factor 5 and most preferably greater by a factor of 10, where the leaching depth is preferably not more than 15 times greater than on the two lateral faces.

This surprising configuration of the glass wafer in embodiments is very advantageous, since it has been found that, in this way, the properties of the glass wafer can be improved in a decisive manner. In particular, this configuration surprisingly makes it possible to improve the mechanical strength of the glass wafer, so as to increase handling and lifetime.

The causes of this are not entirely clear. For instance, it is known that, as also described above, ion exchange can result in an increase in the mechanical strength of a glass, called chemical tempering. However, what is being conducted in the present context is not an ion exchange, but rather an etching operation. This results firstly in removal of the glass as a whole, but the glass network is not dissolved homogeneously, and so it is also possible in particular for certain ions, especially metal ions, to be leached out of the glass network. In other words, the glass network with the network formers remains in a surface region, but with a certain depletion of metal ions.

What has been found is not only that, surprisingly, this can be advantageous for the properties of the glass wafer, for example with regard to adhesion of metallizations applied subsequently to the glass wafer or with regard to the resulting strength. In fact, it has been shown that the leaching in the lateral faces differs from the leaching in the surface of the at least one opening. In particular, it has been shown that the leaching depth in the bushing is greater at least by a factor of 1.1 than the leaching depth on the two lateral faces, preferably greater by a factor of 1.5, particularly preferably greater by a factor of 2, more preferably greater by a factor 5 and most preferably greater by a factor of 10, where the leaching depth is preferably not more than 15 times greater than on the two lateral faces of the wafer.

The causes of this have not been entirely understood. But the inventors are assuming that the reason is the specific manner of performance of the etching, such that, within the narrow opening, different concentration gradients lead for the development of this significant leaching by comparison with the leaching at the surface of the wafer.

The leaching depth and the different development thereof on the lateral faces of the wafer by comparison with the surface of the opening can especially be determined by ToF-SIMS measurement.

Advantageously, this is shown specifically in the case of alkali metal-containing glasses where leaching of alkali metals occurs. It has been found that, for example, when a KOH-containing alkali is used, sodium ions are preferably leached out, where the leaching thereof, as stated above, is different at the lateral faces and the surface of the via. At the same time, in this case, it is possible to see accumulation of potassium ions at the surface of the wafer (in this regard see also FIGS. 8 to 11).

The inventors suspect corresponding effects in the case of leaching of a lithium-containing glass with a KOH- and/or NaOH-containing alkali. The exchange of glasses comprising ions of alkaline earth metals alternatively or additionally to alkali metal ions could also have a corresponding leaching pattern.

In one embodiment, the glass substrate comprises a glass comprising from 30% by weight to 85% by weight of SiO₂. A preferred range for the content of SiO₂ may be from 60% to 84% by weight. It has been found that such a glass is particularly advantageously suitable in order to form a glass wafer in embodiments.

In a further embodiment, the glass wafer is configured such that the fracture resistance of the glass wafer is at least 400 MPa and preferably not more than 650 MPa and/or such that the Weibull modulus of the glass wafer is between 4.2 and 7.1.

In other words, in this embodiment of the wafer, the wafer is particularly fracture-resistant.

In a preferred embodiment, the glass comprises the following components in % by weight based on oxide:

| | |
|---|---|
| B₂O₃ | 5 to 25, preferably 8 to 25 |
| Al₂O₃ | 0 to 25, preferably 0 to 10. |

In yet a further form, the glass wafer has, on at least one surface, especially on at least one of the two lateral faces, a roughness of not more than 1000 nm. The roughness may preferably be less than 100 nm or even less than 10 nm. In one embodiment, the roughness is not more than 1 nm or even less.

It has been found that the glasses enumerated hereinafter are particularly suitable for the production process comprising laser irradiation, formation of filamentary damage and a subsequent etching operation to combine widening channels along the filamentary damage.

In a first embodiment, the composition comprises the following components in % by weight based on oxide:

| | |
|---|---|
| SiO₂ | 30-85 |
| Al₂O₃ | 0-25 |
| B₂O₃ | 5-25 |
| Li₂O + Na₂O + K₂O | 0-30 |
| MgO + CaO + SrO + BaO + ZnO | 0-12 |
| TiO₂ + ZrO₂ | 0-5 |
| P₂O₅ | 0-2 |

The following are advantageous ranges in % by weight based on oxide:

| | |
|---|---|
| SiO₂ | 60-85 |
| Al₂O₃ | 0-10 |
| B₂O₃ | 5-20 |
| Li₂O + Na₂O + K₂O | 0-14 |
| MgO + CaO + SrO + BaO + ZnO | 0-12 |
| TiO₂ + ZrO₂ | 0-5 |
| P₂O₅ | 0-2 |

A further advantageous embodiment comprises % by weight based on oxide:

| | |
|---|---|
| SiO₂ | 60-84 |
| Al₂O₃ | 0-10 |
| B₂O₃ | 3-18 |
| Li₂O + Na₂O + K₂O | 5-20 |
| MgO + CaO + SrO + BaO + ZnO | 0-15 |
| TiO₂ + ZrO₂ | 0-4 |
| P₂O₅ | 0-2 |

Yet a further advantageous embodiment comprises % by weight based on oxide:

| | |
|---|---|
| SiO₂ | 56-65 |
| Al₂O₃ | 14-25 |
| B₂O₃ | 6-11.5 |
| MgO + CaO + SrO + BaO + ZnO | 8-18 |
| ZnO | 0-2 |

Yet a further advantageous embodiment comprises % by weight based on oxide:

| | |
|---|---|
| SiO₂ | 50-81 |
| Al₂O₃ | 0-5 |
| B₂O₃ | 0-5 |
| Li₂O + Na₂O + K₂O | 5-28 |
| MgO + CaO + SrO + BaO + ZnO | 5-25 |
| TiO₂ + ZrO₂ | 0-6 |
| P₂O₅ | 0-2 |

A likewise further advantageous embodiment comprises % by weight based on oxide:

| | |
|---|---|
| SiO₂ | 52-66 |
| B₂O₃ | 0-8 |
| Al₂O₃ | 15-25 |
| MgO + CaO + SrO + BaO + ZnO | 0-6 |
| ZrO₂ | 0-2.5 |
| Li₂O + Na₂O + K₂O | 4-30 |
| TiO₂ + CeO₂ | 0-2.5 |

For all the aforementioned glass compositions, it holds true that, if appropriate, coloring oxides may be added, such as Nd₂O₃, Fe₂O₃, CoO, NiO, V₂O₅, MnO₂, CuO, Cr₂O₃. 0-2% by wt. As₂O₃, Sb₂O₃, SnO₂, SO₃, Cl, F and/or CeO₂ may be added as refining agents, and the total amount of the composition as a whole is 100% by weight in each case.

In a further advantageous embodiment, the glass comprises the following components in % by weight based on oxide:

| | |
|---|---|
| SiO₂ | 30 to 75, preferably 30 to 65 |
| B₂O₃ | 6 to 25, preferably 6 to 10.5 |
| Al₂O₃ | 1 to 15 |
| Na₂O | 1 to 15, preferably 3 to 15 |
| K₂O | 0.5 to 15, preferably 3 to 15 |
| ZnO | 0 to 12 |
| TiO₂ | 0 to 10, preferably 0.5 to 10 |
| CaO | 0 to 0.1. |

In a further advantageous embodiment, the glass comprises the following components in % by weight based on oxide:

| | |
|---|---|
| SiO₂ | 58 to 65 |
| B₂O₃ | 6 to 10.5 |
| Al₂O₃ | 14 to 25 |
| MgO | 0 to 3 |
| CaO | 0 to 9 |
| BaO | 3 to 8 |
| ZnO | 0 to 2. |

It is generally advantageous that the sum total of the contents of MgO, CaO and BaO is characterized in that it is in the range from 0% to 18% by weight or from 0% to 10% by weight or from 0% to 4% by weight.

It has been found to be particularly advantageous for all embodiments when the total content of alkali metals is limited. This means that the sum total of Li₂O+Na₂O+K₂O is advantageously less than 15% by weight, especially advantageously less than 5% by weight.

Advantageous contents of Na₂O for all embodiments are from 0% to 8% by weight, especially from 1% to 5% by weight. Advantageous contents of K₂O for all embodiments are from 0% to 8% by weight, especially from 0% to 3% by weight.

It has been observed, and is applicable to all embodiments, that it is especially advantageous when the content of Li₂O is less than that of Na₂O and/or K₂O. This means that Li₂O/Na₂O<1 and/or Li₂O/K₂O<1. Especially advantageously, the glasses mentioned herein are free of Li₂O. Unavoidable impurities, which may typically be in the range up to 5 ppm, may of course be present even then.

It has been found that, surprisingly, the wafer, in embodiments of the present disclosure, is particularly well suited for interconnection technology, especially for the provision of very high data speeds. What are needed for this purpose are actually comparatively small vias. In addition, it has been found that the selective leaching of metal ions, especially of alkali metal ions, allows metallizations to have particularly good adhesion on the wafer, specifically also in the region of the via or passage opening itself.

Metallizations, for example comprising or composed of Ni, Cr, Ti, Pd, which may also function as adhesion promoters between the glass substrate or wafer and further layers, for example further metal layers, may, for example, be applied electrolessly (electroless plating) or electrolytically.

In a preferred embodiment, the metallization comprises copper, silver, gold or aluminum. The copper-comprising layer may be applied directly to the glass wafer or to an adhesion-promoting layer, for example comprising or composed of Ni, Cr, Ti, Pd, disposed between the glass wafer and the copper-comprising layer. In a further embodiment, the metallization may consist predominantly, i.e. to an extent of more than 50% by weight, or essentially, i.e. to an extent of more than 90% by weight, or entirely, of copper.

The excellent adhesion of metallizations can be demonstrated by way of example by means of a scratch test on the surface of a metallized wafer, as elucidated in detail further down. A further method is the “Tesa test”, in which an adhesive strip is bonded to the sample and the force required to pull away the adhesive strip along with the coating is measured.

The invention also relates to a process.

The process for producing a glass wafer comprising a glass substrate comprising at least one opening, having two mutually opposite lateral faces and one circumferential edge face, especially a glass wafer according to one embodiment of the present disclosure, comprises the steps of:
providing a glass substrate in pane form,
directing a laser beam from an ultrashort pulse laser onto one of the lateral faces of the glass substrate in pane form, wherein the laser beam is formed by focusing optics to an elongated focus in the glass substrate in pane form such that the incident energy of the laser beam creates filamentary damage in the volume of the glass substrate in pane form, the longitudinal direction of which is at right angles to at least one of the lateral faces of the glass substrate in pane form, and wherein the filamentary damage by the ultrashort pulse laser is created by incidence of a pulse or pulse packet having at least two successive laser pulses,
etching the glass substrate in pane form at least in the region in which filamentary damage has formed in the glass substrate in pane form in a liquid etch medium, wherein the filamentary damage is widened to channels, wherein the liquid etch medium is or comprises an alkali, preferably a potassium-containing alkali.

The inventors have found that precisely such an operation, especially with etching by means of an alkali, is particularly advantageous.

This is because it has been found that metallizations applied to the wafer have better durability when the etching is effected by means of an alkali, compared to etching by means of an acid.

This is because etch treatment with an alkali seems to have the effect that fewer metal ions overall, especially fewer alkali metals and or alkaline earth metals, are leached out of the glass network. This appears to result in better adhesion of the metallization on the glass. The inventors suspect that this is because there is a diffusion process from the glass into the metallization.

As already set out above, it has been found that it is possible in this way to obtain a glass wafer in which the leaching in an opening is distinctly different from the leaching at the surface of the glass wafer, i.e. on the two lateral faces in particular.

In particular, the leaching depth in the opening is higher than the leaching depth on the surface.

In other words, more significant leaching appears to take place in the openings than at the surface of the glass wafer. Nevertheless, it has been found that, even in the openings, very good contact of the metallization on the glass surface is still possible.

Etching with a potassium-containing alkali, preferably an aqueous potassium-containing alkali, appears to be particularly advantageous here. This is because a particularly advantageous leaching profile is established in this way, which may be found to be advantageous in subsequent processing steps in the production of an interposer. Particular mention should be made here of better adhesion of the metallization on the etched glass surface.

The etching can preferably be effected at a temperature of at least 110° C., for example at 115° C. or 120° C., i.e. with an etch medium having a temperature of at least 110° C., preferably at least 115° C., preferably of not more than 150° C.

In this way, the exceptional surface structure of the glass wafer seems to arise in a particularly simple manner.

It has been found that, surprisingly, no change in the other parameters of the process regime is absolutely necessary in order to achieve advantageous properties of the glass wafer. In particular, there is no need to adjust the laser parameters for creation of filaments that are needed to obtain the corresponding openings in the glass wafer at a later stage, in order, for example, to improve the strength of the glass wafer compared to prior art glass wafers. Instead, adjustment of the etching parameters surprisingly appears to be sufficient to achieve improved properties here, in particular the temperature of the etch bath.

In one embodiment, the glassy material of the glass substrate in pane form is removed at a removal rate of less than 5 μm per hour. This appears to be advantageous because a different surface structure seems to form in this way than in the case of higher material removal rates. In particular, this seems to result in selective removal of the glass substrate, which appears to be advantageous with regard to the mechanical properties of the resulting glass wafer. With regard to the resulting bond strength too, it appears to be advantageous when comparatively slow material removal is chosen. The inventors suspect that this results in comparatively selective material removal and that the surface structure that forms is correspondingly more favorable; in particular, certain substances such as metal ions can be leached out to a lesser degree. The inventors suspect here that this could possibly result in a kind of “tempering effect”—or, alternatively, by comparison with significant, rapid material removal over the full area, the result is less significant weakening of the glass structure, which is advantageous in the later handling of the glass wafer.

In one embodiment, the etching time is at least 12 hours. It is also the case that comparatively slow or longer-lasting etching can have the effect of obtaining an advantageous increase in the mechanical stability of the resulting glass wafer.

In one embodiment, the number of pulses in a burst for introduction of filamentary damage is at least 2 or at most 7.

It is alternatively possible and may be preferable to create the filamentary damage with just one laser pulse and not in the form of a pulse packet.

In yet a further embodiment, the pulse duration of the laser is in the range from 0.5 ps to 2 ps.

In yet a further embodiment, at least one surface is mechanically polished. This is particularly advantageous for establishment of a low roughness and, in addition, this can also contribute to another increase in mechanical strength of the glass wafer.

Particularly preferably, the polishing follows after the etching.

### BRIEF DESCRIPTION OF THE DRAWINGS

The invention is elucidated in detail hereinafter with reference to drawings. The figures show:

FIG. 1 illustrates a perspective view of a glass wafer in one embodiment,

FIG. 2 illustrates a section view of a glass wafer in one embodiment,

FIG. 3 illustrates a schematic diagram of the process for producing a glass wafer in one embodiment,

FIGS. 4 and 5 illustrate a representation of fracture probabilities of different glass wafers,

FIGS. 6 and 7 illustrate ToF-SIMS profiles for illustration of the different leaching of glass wafers depending on the etch medium,

FIGS. 8 to 11 illustrate ToF-SIMS profiles for illustration of the different surface structure in the opening and on the lateral face of glass wafers in embodiments,

FIGS. 12 to 15 illustrate ToF-SIMS profiles of differently pretreated and metallized glass wafers, and

FIGS. 16 to 17 illustrate representations of scratch traces on metallized glass wafers.

### DETAILED DESCRIPTION OF THE INVENTION

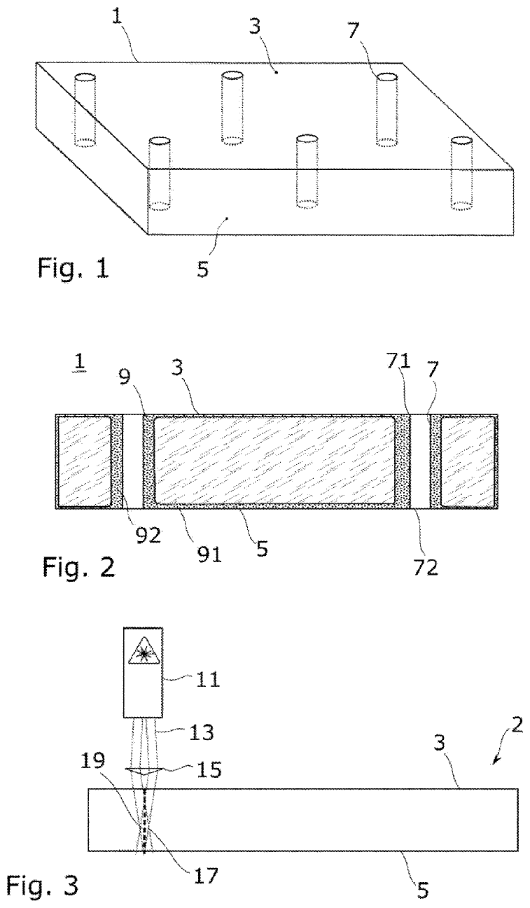

FIG. 1 shows a schematic perspective view, not to scale, of a glass wafer 1 in one embodiment. The glass wafer 1 comprises a glass substrate (not labelled here) comprising at least one opening 7, which can also be referred to as a via in the context of the present disclosure. The glass substrate or, accordingly, the glass wafer 1 as well comprises two mutually opposite lateral faces 3, 5. The glass wafer 1, and in a corresponding manner also the glass substrate, comprise a glass comprising at least one network former, preferably SiO₂, and at least one metal oxide. The glass thus takes the form of a multicomponent glass, which brings distinct benefits over a pure quartz glass, for example. In particular, the glass is thus amenable to a production and shaping process in a customary melting procedure.

FIG. 2 shows a section view of a glass wafer 1 in one embodiment. Two openings 7 are shown in section here, visible as holes 71, 72 on the respective sides 3, 5 of the glass wafer 1. Also shown is the depletion zone 9 caused by the etching process. This is divided into two regions, namely the region 91 formed on both lateral faces 3, 5 of the glass wafer 1 with only a low depletion depth or leaching depth, and the region 92 formed in the opening 7 with a distinctly greater leaching depth. The leaching depth, especially for metal ions in the region of the opening 7, is greater at least by a factor of 1.1 than the leaching depth on the two lateral faces, preferably greater by a factor of 1.5, particularly preferably greater by a factor of 2, more preferably greater by a factor 5 and most preferably greater by a factor of 10, where the leaching depth is preferably 15 times greater than on the two lateral faces 3, 5 of the glass wafer 1. This can preferably be determined in a ToF-SIMS measurement.

FIG. 3 shows, in a schematic view that is not true to scale, by way of example, a process for producing a glass wafer 1 that is not labelled here. For this purpose, a glass substrate 2 is provided. The sides 3, 5 of the glass substrate 2 correspond to the sides of the later glass wafer 1.

An ultrashort pulse laser 11 is used to generate a laser beam 13, which is directed onto the glass substrate 2. The focusing optics 15 form an elongated focus 17 in the glass substrate 2 in pane form, such that the incident energy in the laser beam 13 creates filamentary damage 19 in the volume of the glass substrate 2 in pane form, the longitudinal direction of which is at right angles to the surface of the glass substrate 2 or to at least one of the two lateral faces 3, 5 of the glass substrate 2.

This operation can additionally also be repeated at different points on the glass substrate. Later on in the process, an opening is then created from the filamentary damage 19, and this serves as a via in the interposer.

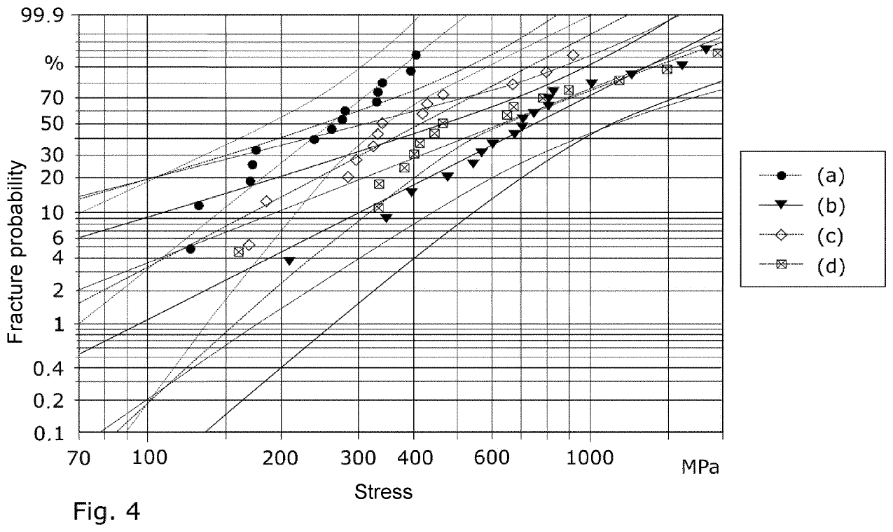

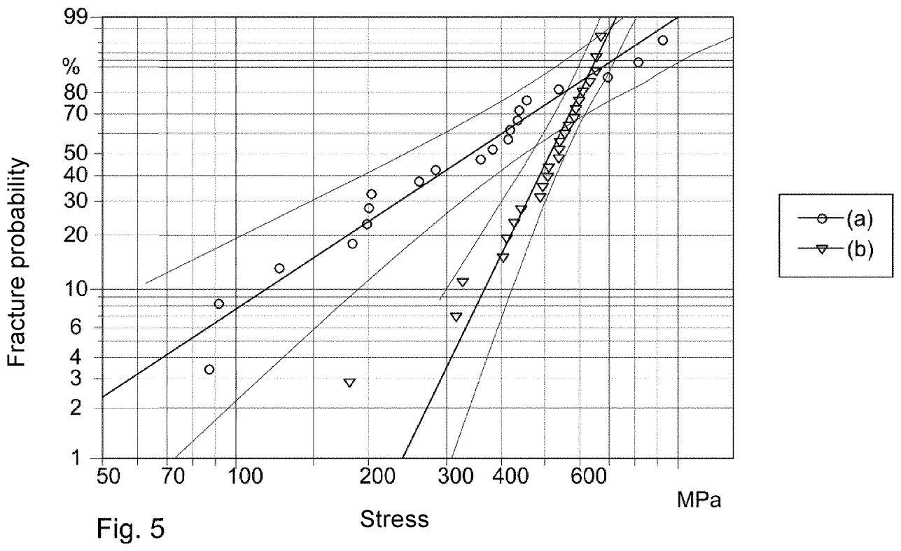

FIG. 4 shows a representation of strengths of glass wafers depending on the etch medium used or on glass substrates that have undergone a different pretreatment. All measurement data were obtained without introducing openings into the wafers or substrates in question. As usual in representing the strength of brittle material, the points are shown in a log-log Weibull diagram. This is also correspondingly applicable to FIG. 5.

The measurement points a) (black filled points) are fracture probabilities of glass substrates that have neither been etched nor otherwise pretreated, and thus constitute the reference with regard to fracture probability. The points b) (black film triangles) represent fracture probabilities determined for glass wafers that have been etched by KOH. The points c) (unfilled square on point) are fracture probabilities for wafers that have been etched by HF. Finally, the points d) (square containing a cross) show fracture probabilities for a polished wafer.

As shown by the fracture probability depending on the tension acting on the substrate or wafer, distinct differences are found here. Accordingly, the wafers etched by KOH show an improvement in mechanical stability, even by comparison with completely unetched substrates and especially also to HF-etched samples.

This is true in particular when temperatures of the etch bath, i.e. of the alkali used, for example of a KOH-comprising alkali, of at least 110° C., preferably of at least 115° C., are established, for example of 120° C. This is because, as set out, it has been found that the fracture probability of a glass can be significantly influenced by the choice of etch medium and also by the temperature thereof. This may also be shown for the structured substrate, i.e. the resulting glass wafer.

FIG. 5 shows the fracture probabilities as a function of the stress acting on a wafer for two different types of wafer. “a)” (unfilled circles) here shows the fracture probability data for a glass wafer that were obtained on a 1 mm-thick wafer with openings having a diameter of 50 μm. The etching was effected using HF. These are to be compared with the points b) (unfilled triangle on point), which show fracture probabilities for a 1 mm-thick wafer that has been etched with KOH and in which the openings have a diameter of 10 μm.

The characteristic strength, σ_{c}, and the Weibull modulus for these samples are compiled in the following table, with the confidence interval given in brackets in each case:

[MPa]

| Samples | σ_{c} [MPa] | Weibull modulus |
|---|---|---|
| a) HF-etched | 421.3 (336.7 . . . 557.6) | 1.759 (1.337 . . . 2.316) |
| b) KOH-etched | 550.8 (515.7 . . . 597.2) | 5.506 (4.273 . . . 7.095) |

The characteristic value and Weibull modulus are the two parameters of a Weibull distribution. The strengths of brittle materials are typically described by Weibull distributions. Characteristic strength is then one of the two parameters that define the distribution.

As can be inferred from these data, the data for characteristic strength and for the Weibull modulus are dependent on the etching method. The effect here is that, by means of an alkali, KOH here, etched glass wafers have a higher strength.

It can be shown here that samples etched by HF have a significant increase in leaching and depletion of metal ions, especially of alkali metal ions, for example sodium and potassium ions, relative to etching by means of an alkali such as KOH.

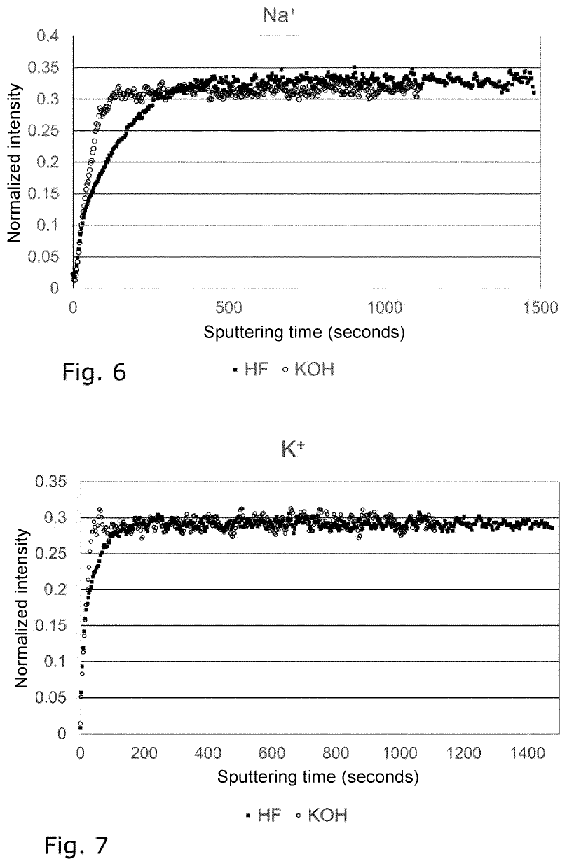

This is illustrated by way of example in FIGS. 6 and 7, which each show ToF-SIMS profiles of glass wafers that have been etched by HF (filled circles) or KOH (unfilled circles). It is shown here clearly that the samples etched by KOH have become less significantly depleted of metal ions, here of the ions of sodium and potassium, than glass wafers etched by HF.

The inventors suspect that this lower depletion of the surface zone of a glass wafer leads to the observed improvement in strength. It is generally assumed for glass that the depletion of sodium in a surface zone increases the spread of cracks in a glass. A sodium-depleted surface layer has lower density compared to the non-sodium-depleted glass, which should lead to formation of tensile stresses at the surface. This in turn should lead to elevated probability of cracking and crack growth, which ultimately leads to failure by fracture.

Any etching method likewise leads intrinsically to leaching and to depletion of metal ions, for example of ions of sodium, but the exact formation of this depletion zone appears to be critical specifically for structured substrates or for wafers comprising openings. The inventors suspect that this could be connected to the method of laser structuring, since the laser treatment initially induces microcracks in the substrate/wafer. Here, however, etching is initially advantageous if anything since the etching and the associated removal of material result initially in elimination of such microcracks and initially prevent further crack propagation. However, as observed and set out, HF or acidic etching results in obviously much greater depletion of metal ions, which somewhat reduces this positive effect. Alkaline etching has advantages here because there is not such significant leaching of metal ions, especially of sodium, which better promotes the minimization of crack propagation. The inventors suspect that the correlations of sodium depletion leading to an increase in fracture probability that are generally applicable to glass are applicable not just to sodium but generally to metal ions, such that, overall, the improvement in mechanical strength of the structured glass wafers compared to the prior art wafers could be attributable to the reduced leaching overall compared to known wafers.

The inventors suspect that this could be attributable to the mechanism of the acidic etching, for example by HF, which first includes adsorption of the fluorine anion on the glass surface, and of leaching of metal ions, especially of alkali metal and/or alkaline earth metal ions, so as to form a porous layer on the glass surface, followed by rapid breakage of Si—O—Si or X—O—Si bonds (X here represents a further network former, for example aluminum or boron).

The inventors suspect that, in the case of alkaline etching, by contrast, there is comparatively uniform material removal that weakens the bonds by the network formers to a lesser degree. In this way, the surface chemistry of the glass is kept more intact than by etching with an acid such as HF. Although this has the advantage of a faster process, it obviously entails distinct drawbacks with regard to the resulting product, such as reduced mechanical strength.

Interestingly, it has been found that this lower leaching of the surface also brings benefits when subsequent processing steps are considered. For instance, probably as a result of the interdiffusion of metal ions into subsequently applied metallizations, such can adhere better on the glass wafer.

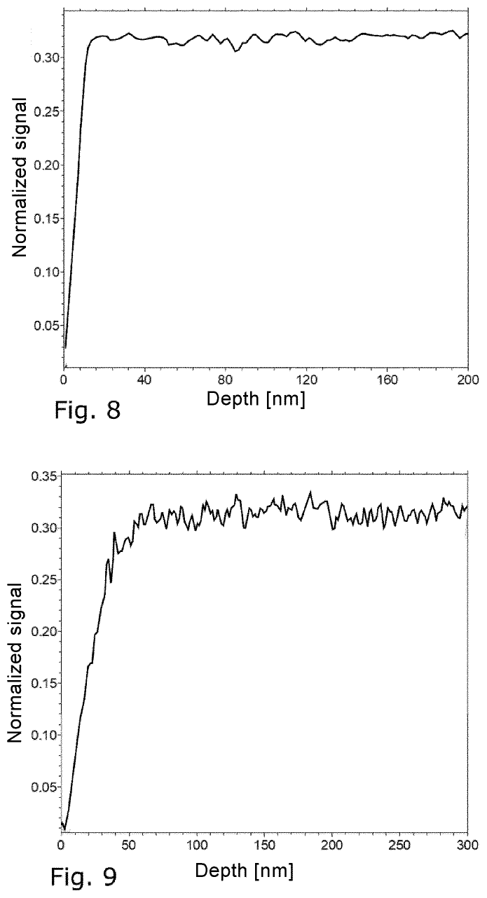

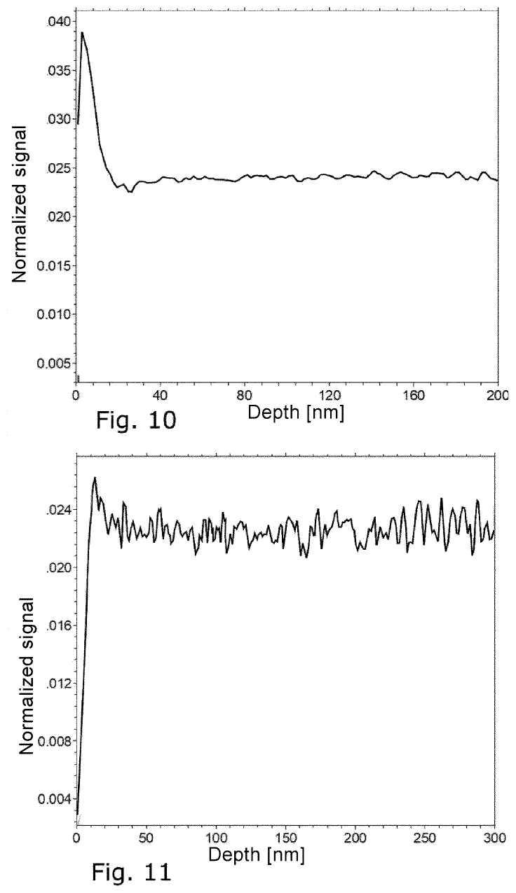

The differences in leaching depth between the lateral faces and the surfaces in the opening are shown by FIGS. 8 to 11. What can be seen here in each case are ToF-SIMS profiles of metal ions, namely of sodium ions in FIGS. 8 and 9 and of potassium ions in FIGS. 10 and 11. It is clearly apparent that leaching in the interior of the opening (FIG. 9) is more significant than at the lateral face (FIG. 8) for sodium ions in the case of leaching with KOH-comprising alkali. FIGS. 10 (lateral face) and 11 (interior of the opening) if anything show enrichment of potassium ions in the near-surface region.

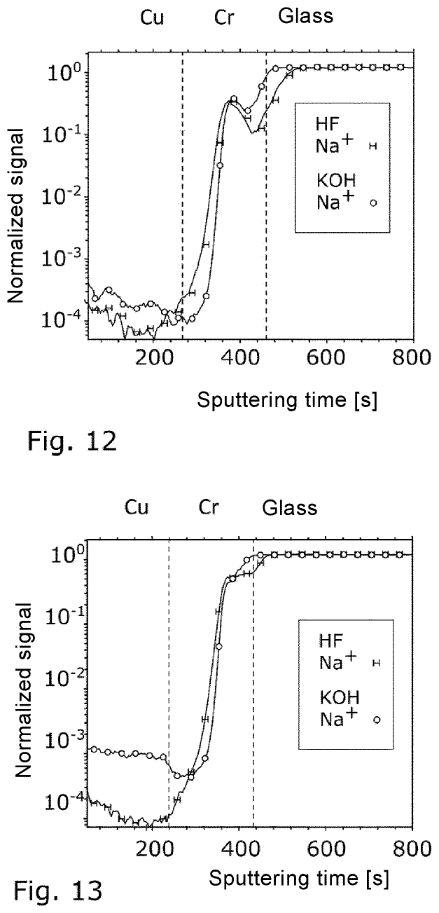

FIGS. 12 to 17 illustrate the difference between prior art glass wafers and those glass wafers corresponding to embodiments of the present disclosure. The glass wafers have each been metallized because, in this way, the difference in the glass wafers and the mode of pretreatment is at its clearest and this corresponds to the application.

The metallized glass wafers are, by way of example, glass wafers that have been obtained by a process according to the prior art, etching with HF here, and according to details in the present disclosure. Metallization was effected at 100° C. in each case, first by applying an adhesion-promoting layer, first chromium and then titanium, followed by a copper metallization. The deposition temperature was 100° C. Bond strength can generally be improved at a higher deposition temperature, showing the advantageous effect of etching preferably at this lower temperature. In general, however, deposition temperatures for the metallization of up to 400° C. or even more are possible.

FIGS. 12 and 13 show the ToF-SIMS profiles on wafers metallized at 100° C. with chromium as adhesion-promoting layer between glass and copper. As can be seen, the level of sodium (FIG. 12) and potassium (FIG. 13) in the glass, i.e. in the bulk region of the metallized glass wafer, is identical in each case. Differences arise, however, with regard to the sodium or potassium content (each shown by the signal of the singly positively charged ions of sodium and potassium). The level of sodium or potassium in the region of the copper metallization is higher after etching with KOH than after etching with HF. The inventors suspect that this is because the lower leaching of the glass surface by the treatment with KOH causes the corresponding metal ion to diffuse more quickly into the metallization, hence ensuring better adhesion overall. Since this effect of leaching depth is even more marked in the surfaces of the opening, the inventors assume that the metallization adheres even better in the opening itself than is already the case in the region of the lateral faces of the wafer.

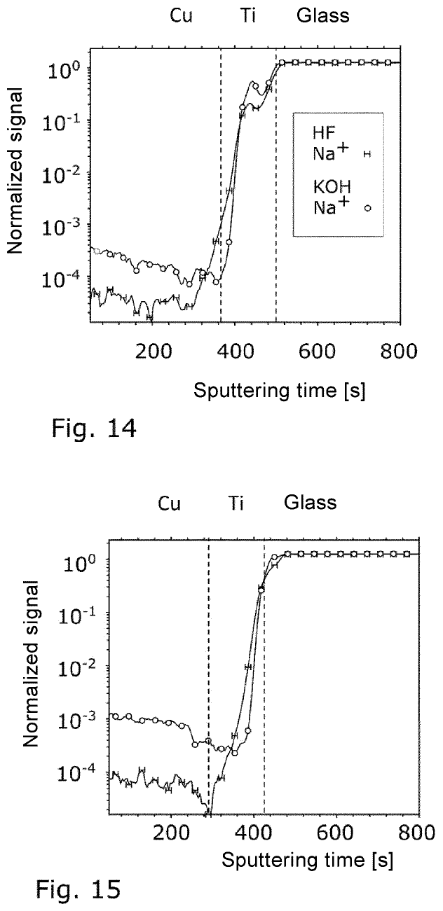

The corresponding picture is shown with regard to the use of an adhesion-promoting titanium layer between glass surface and copper layer in FIGS. 14 and 15. Here too, the level of sodium (FIG. 14) and potassium (FIG. 15) in the glass, i.e. in the bulk region of the metallized glass wafer, is identical in each case. Differences likewise arise, however, with regard to the sodium or potassium content (each shown by the signal of the singly positively charged ions of sodium and potassium). The level of sodium or potassium in the region of the copper metallization is higher after etching with KOH than after etching with HF. The inventors suspect that this is because the lower leaching of the glass surface by the treatment with KOH causes the corresponding metal ion to diffuse more quickly into the metallization, hence ensuring better adhesion overall. Since this effect of leaching depth is even more marked in the surfaces of the opening, the inventors assume that the metallization adheres even better in the opening itself than is already the case in the region of the lateral faces of the wafer.

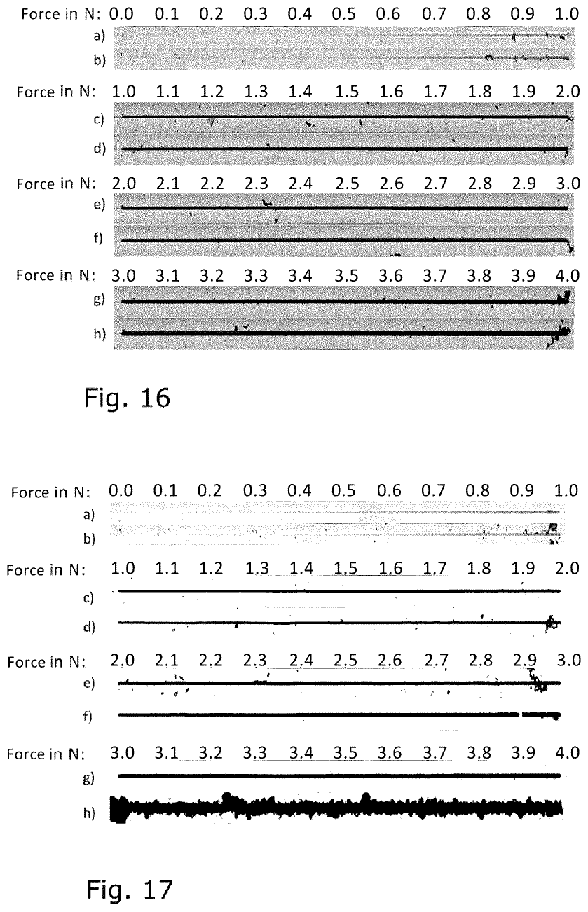

Finally, FIGS. 16 and 17 show a representation of scratch traces on differently etched glass wafers that were then metallized. The adhesion-promoting layer used was titanium.

The scratch resistance of the metallization is generally determined by the Knoop scratch test, which is a standard procedure for the determination of scratch resistance and simultaneously bond strength of metallizations in the coating and metallization industry. Such a test involves applying a diamond tip to the surface of the coating to be tested and moving this tip over a distance at constant speed. The force acting on the tip may be constant or may increase continuously over the test distance. For the samples shown in FIGS. 16 and 17, the force was increased continuously over a test distance. The corresponding forces are indicated in the respective figures. The load from which failure of the layer occurs is noted. Failure of the layer involves occurrence of the first cracks in the layer alongside the scratch trace itself, which can then often lead subsequently to shell chips or else flaking. The load from which failure occurs as a result of cracking is ascertained by means of visual inspection by microscope. This load is also referred to as critical load, LC.

FIG. 16 shows a metallization where the glass wafer has been etched by KOH.

Subsequently, an adhesion-promoting titanium layer was applied, and then a copper layer. The temperature in the metallization was 100° C. because this is the more critical case, as also already elucidated above.

The diagram of FIG. 16 shows:
0.03 N and 1 N (5 mm) no delamination (a, b)
1 N and 2 N (5 mm) no delamination (c, d)
2 N and 3 N (5 mm) no delamination (e, f)
3 N and 4 N (5 mm) no delamination (g, h)

By comparison, FIG. 17 shows the scratch trace for a metallized glass wafer that was metallized like the glass wafer of FIG. 16, except that the glass wafer was etched by HF. FIG. 17 shows:
0.03 N and 1 N (5 mm) no delamination (a, b)
1 N and 2 N (5 mm) no delamination (c, d)
2 N and 3 N (5 mm) delamination in 1 of 2 measurements from a critical force of about 2.9 N (e, f)
3 N and 4 N (5 mm) delamination in 1 of 2 measurements from a critical force of 3 N (g, h).

As stated, the adhesion of metallizations is thus better for glass wafers etched by means of a basic etch in embodiments.

### LIST OF REFERENCE NUMERALS

| | |
|---|---|
| 1 | glass wafer |
| 2 | glass substrate |
| 3, 5 | lateral faces of 1 |
| 7 | opening |
| 71, 72 | holes in lateral face |
| 9 | depletion zone |
| 91 | region 9 on lateral face 3 or 5 |
| 92 | region 9 in opening 7 |
| 11 | ultrashort pulse laser |
| 13 | laser beam |
| 15 | focusing optics |
| 17 | focus |
| 19 | filamentary damage |

1-10. (canceled)

11. A glass wafer, comprising:
a glass substrate comprising at least one opening having a surface having two mutually opposite lateral faces and one circumferential edge face, the glass substrate comprising a glass comprising a network former and at least one metal oxide, the at least one opening having a maximum lateral dimension of not more than 400 μm, wherein the glass wafer has a thickness of at least 10 μm, wherein a leaching depth of alkali metal ions in the surface of the at least one opening is greater at least by a factor of 1.1 than a leaching depth on the two lateral faces.

12. The glass wafer of claim 11, wherein the maximum lateral dimension is a diameter of the at least one opening.

13. The glass wafer of claim 11, wherein the leaching depth in the surface of the at least one opening is not more than 15 times greater than the leaching depth on the two lateral faces.

14. The glass wafer of claim 11, wherein the glass substrate comprises a glass comprising 30% by weight to 85% by weight of SiO₂.

15. The glass wafer of claim 11, wherein a characteristic strength of the glass wafer is at least 400 MPa and at most 650 MPa and/or a Weibull modulus of the glass wafer is between 4.2 and 7.1.

16. The glass wafer of claim 11, wherein the glass comprises the following components in % by weight based on oxide:

| | |
|---|---|
| B₂O₃ | 5 to 25; and |
| Al₂O₃ | 0 to 25. |

17. The glass wafer of claim 11, wherein the glass wafer has, on at least one surface, a roughness of not more than 1000 nm.

18. The glass wafer of claim 17, wherein the at least one surface with the roughness of not more than 1000 nm is at least one of the two lateral faces.

19. The glass wafer of claim 11, wherein the glass comprises the following components in % by weight based on oxide:

| | |
|---|---|
| SiO₂ | 30-85; |
| Al₂O₃ | 0-25; |
| B₂O₃ | 5-25; |
| Li₂O + Na₂O + K₂O | 0-30; |
| MgO + CaO + SrO + BaO + ZnO | 0-12; |
| TiO₂ + ZrO₂ | 0-5; and |
| P₂O₅ | 0-2. |

20. The glass wafer of claim 19, wherein the glass comprises Li₂O+Na₂O+K₂O from 0 to <15% by weight.

21. The glass wafer of claim 20, wherein a ratio of the weight percentages of Li₂O/Na₂O<1 and/or a ratio of the weight percentages of Li₂O/K₂O<1.

22. The glass wafer of claim 11, wherein the leaching depth of alkali metal ions in the surface of the at least one opening is greater at least by a factor of 10 than the leaching depth on the two lateral faces.

23. The glass wafer of claim 11, wherein the maximum lateral dimension is not more than 200 μm.

24. The glass wafer of claim 11, wherein the glass comprises the following components in % by weight based on oxide:

| | |
|---|---|
| SiO₂ | 60-85; |
| Al₂O₃ | 0-10; |
| B₂O₃ | 5-20; |
| Li₂O + Na₂O + K₂O | 0-14; |
| MgO + CaO + SrO + BaO + ZnO | 0-12; |
| TiO₂ + ZrO₂ | 0-5; and |
| P₂O₅ | 0-2. |

25. The glass wafer of claim 11, further comprising a metallization in at least one region of at least one of the lateral faces and/or at least one region of the surface of the at least one opening.

26. A process for producing a glass wafer comprising a glass substrate comprising at least one opening, having two mutually opposite lateral faces and one circumferential edge face, comprising:
providing the glass substrate in pane form;
directing a laser beam from an ultrashort pulse laser onto one of the lateral faces of the glass substrate in pane form, wherein the laser beam is formed by focusing optics to an elongated focus in the glass substrate in pane form such that incident energy of the laser beam creates filamentary damage in a volume of the glass substrate in pane form, a longitudinal direction of which is at right angles to at least one of the lateral faces of the glass substrate in pane form, and wherein the filamentary damage by the ultrashort pulse laser is created by incidence of a pulse or pulse packet having at least two successive laser pulses; and
etching the glass substrate in pane form at least in a region in which filamentary damage has formed in the glass substrate in pane form in a liquid etch medium, wherein the filamentary damage is widened to channels, wherein the liquid etch medium is or comprises an alkali.

27. The process of claim 26, wherein the liquid etch medium comprises a potassium-containing alkali.

28. The process of claim 26, wherein at least one of the following is satisfied:
a glassy material of the glass substrate in pane form is removed at a removal rate of less than 5 μm per hour;
an etching time of the etching is at least 12 hours;
the liquid etch medium has a temperature of at least 110° C.;
a number of the laser pulses in a burst for introduction of filamentary damage is at least 2 or at most 7;
a pulse duration of the laser is in a range from 0.5 ps to 2 ps; or
at least one surface of the glass substrate is mechanically polished.
